(19) United States
(12) Patent Application Publication
(10) Pub. No.: US 2020/0158673 A1
(43) Pub. Date: May 21, 2020

(54) HUMIDITY SENSOR

(71) Applicant: MINEBEA MITSUMI Inc., Nagano (JP)

(72) Inventor: Taketomo NAKANE, Tokyo (JP)

(21) Appl. No.: 16/566,049

(22) Filed: Sep. 10, 2019

(30) Foreign Application Priority Data
Nov. 16, 2018 (JP) 2018-215851
Nov. 16, 2018 (JP) 2018-215853

(51) Int. Cl. G01N 27/22; H01L 23/495; H01L 29/861; H01L 33/56; H01L 23/60

(52) U.S. Cl. CPC G01N 27/223; H01L 23/49513; H01L 23/60; H01L 33/56; H01L 29/8618

(57) ABSTRACT

A humidity sensor includes a first semiconductor chip having a first side and a second side opposing each other, and including a humidity sensing part and pads arranged along the first side, a second semiconductor chip mounted with the first semiconductor chip and configured to process signals input via bonding wires coupled to the pads, and an encapsulating member having an opening exposing the humidity sensing part. The opening has a center position closer to the second side than a center position of the first semiconductor chip.

### CROSS-REFERENCE TO RELATED APPLICATIONS

This application is based on and claims priority to Japanese Patent Application No. 2018-215851 filed on Nov. 16, 2018, and Japanese Patent Application No. 2018-215853 filed on Nov. 16, 2018, the entire contents of which are incorporated herein by reference.

### BACKGROUND OF THE INVENTION

### 1. Field of the Invention

The present invention relates to a humidity sensor. The humidity sensor is sometimes also referred to as a humidity sensing device, a humidity detector, a humidity detection device, or the like.

### 2. Description of the Related Art

Humidity sensors include an electrostatic capacitance type humidity sensor that uses, as a dielectric, a humidity sensing layer formed by a polymer material having a dielectric constant that changes depending on adsorbed moisture content. In the electrostatic capacitance type humidity sensor, the humidity sensing layer is arranged between a pair of electrodes, and the humidity (or relative humidity) is obtained by measuring the electrostatic capacitance between the pair of electrodes. An example of the electrostatic capacitance type humidity sensor is described in International Publication Pamphlet No. WO2012/046501 (or Japanese Patent No. 5547296), for example.

The humidity sensor may have a stacked structure in which a sensor chip having a humidity sensing part is mounted on a substrate or the like, and the sensor chip and the substrate or the like are encapsulated by a resin encapsulating member, to form a sensor package. In addition, the sensor chip is electrically connected to the substrate or the like via bonding wires, for example.

The humidity sensing part needs to contact outside air that is the sensing target. For this reason, the encapsulating member that encapsulates the sensor chip or the like includes an opening that exposes the humidity sensing part. An example of such a humidity sensor is described in Japanese Laid-Open Patent Publication No. 2018-59716, for example.

The humidity sensor requires the opening in the encapsulating member to expose the humidity sensing part. On the other hand, the bonding wires need to be covered by the encapsulating member, so as not to be exposed to the outside.

The opening in the encapsulating member may be made large in order to positively expose the humidity sensing part from the encapsulating member. However, if the opening is simply made large, the bonding wires may become exposed at the opening due to a mounting error or the like generated during the manufacturing process. For this reason, the opening needs to be arranged at an appropriate position of the sensor chip, without making the opening large.

Accordingly, during the manufacturing process of the humidity sensor, defects such as exposure of the bonding wires or the like may be generated when forming the opening, to deteriorate the yield of the humidity sensor, unless the opening is arranged to the appropriate position.

### SUMMARY OF THE INVENTION

Embodiments of the present invention can provide a humidity sensor, which can improve the yield during the manufacturing process.

According to one aspect of embodiments of the present invention, a humidity sensor including a first semiconductor chip having a first side and a second side opposing each other, the first semiconductor chip including a humidity sensing part, and a plurality of pads arranged along the first side; a second semiconductor chip, mounted with the first semiconductor chip, and configured to process signals input via a plurality of bonding wires coupled to the plurality of pads; and an encapsulating member having an opening exposing the humidity sensing part, the opening having a center position closer to the second side than a center position of the first semiconductor chip.

Other objects and further features of the present invention will be apparent from the following detailed description when read in conjunction with the accompanying drawings.

### BRIEF DESCRIPTION OF THE DRAWINGS

FIG. 1A, FIG. 1B, and FIG. 1C are diagrams illustrating an example of a general configuration of a humidity sensor according to one embodiment of the present invention;

FIG. 2 is a cross sectional view schematically illustrating a cross section along a line A-A in FIG. 1A;

FIG. 3 is a plan view illustrating the humidity sensor in a state where a mold resin is removed;

FIG. 4 is a plan view illustrating a general configuration of a sensor chip;

FIG. 5 is a circuit diagram illustrating an example of a configuration of an ESD protection circuit;

FIG. 6 is a diagram illustrating a layer structure of a NMOS transistor forming the ESD protection circuit;

FIG. 7 is a circuit diagram illustrating an example of a configuration of a humidity sensing part;

FIG. 8 is a circuit diagram illustrating an example of a configuration of a temperature sensing part;

FIG. 9 is a cross sectional view for explaining a device structure of the sensor chip;

FIG. 10 is a plan view illustrating an example of shapes of a lower electrode and an upper electrode;

FIG. 11 is a plan view illustrating an example of a n-type diffusion layer forming a heater part;

FIG. 12 is a block diagram illustrating an example of a functional configuration of an ASIC chip;

FIG. 13 is a diagram for explaining a position where an opening is formed;

FIG. 14A and FIG. 14B are diagrams for explaining an example of manufacturing processes of the humidity sensor;

FIG. 15A and FIG. 15B are diagrams for explaining the example of the manufacturing processes of the humidity sensor;

FIG. 16A and FIG. 16B are diagrams for explaining the example of the manufacturing processes of the humidity sensor;

FIG. 17A and FIG. 17B are diagrams for explaining the example of the manufacturing processes of the humidity sensor;

FIG. 18 is a diagram illustrating an example of a temperature sensing part formed by a resistance type temperature sensor;

FIG. 19 is a circuit diagram illustrating an example of the configuration of the ESD protection circuit according to a modification; and

FIG. 20 is a diagram illustrating the layer structure of a PMOS transistor forming the ESD protection circuit.

### DESCRIPTION OF THE PREFERRED EMBODIMENTS

Embodiments of the present invention will be described, by referring to the drawings. In the drawings, those parts that are the same are designated by the same reference numerals, and a repeated description of the same parts may be omitted. In this specification, the “humidity” described refers to the “relative humidity”.

[General Configuration]

The configuration of a humidity sensor 10 according to one embodiment of the present invention will be described.

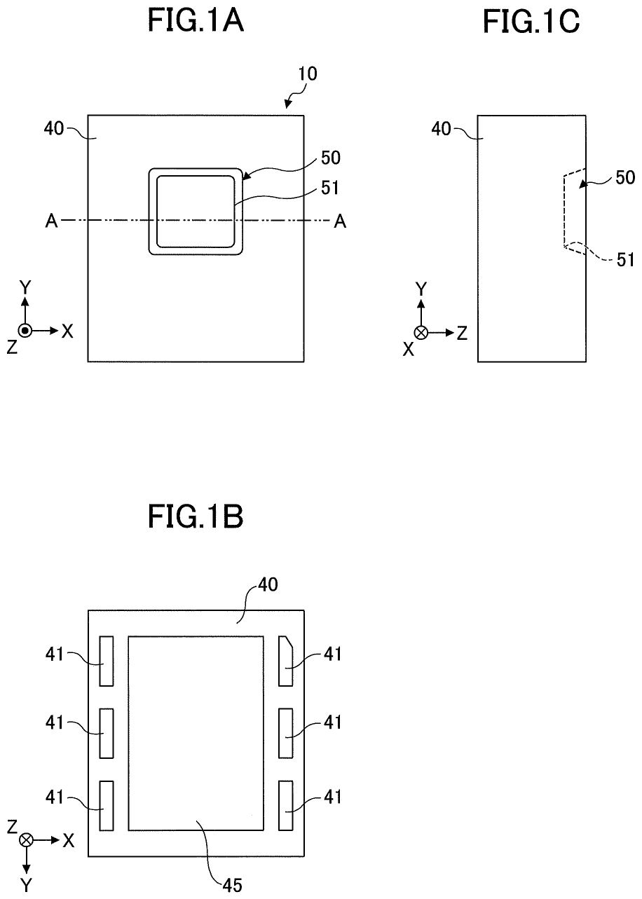

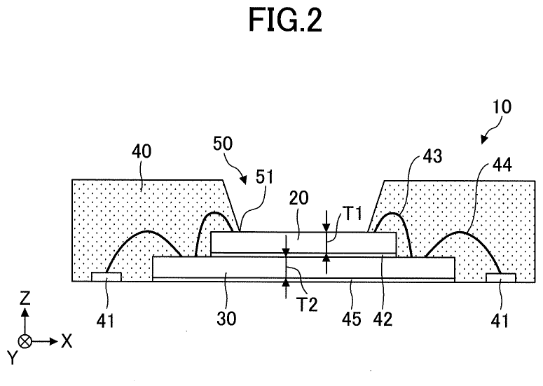

FIG. 1A, FIG. 1B, and FIG. 1C are diagrams illustrating an example of the general configuration of the humidity sensor 10 according to one embodiment of the present invention. FIG. 1A is a plan view viewed from above the humidity sensor 10. FIG. 1B is a bottom view viewed from below the humidity sensor 10. FIG. 1C is a side view viewed from the side of the humidity sensor 10. Further, FIG. 2 is a cross sectional view schematically illustrating a cross section along a line A-A in FIG. 1A.

The humidity sensor 10 has a planar shape that is an approximate rectangular shape having a first pair of opposing sides extending parallel to a X-direction, and a second pair of opposing sides extending parallel to a Y-direction which is perpendicular to the X-direction. The humidity sensor 10 has a thickness along a Z-direction that is perpendicular to both the X-direction and the Y-direction. The planar shape of the humidity sensor 10 may be other than the rectangular shape, such as a circular shape, an oval shape, a polygonal shape, or the like.

The humidity sensor 10 includes a sensor chip 20 forming an example of a first semiconductor chip, an Application Specific Integrated Circuit (ASIC) chip 30 forming an example of a second semiconductor chip, a mold resin 40, and a plurality of lead terminals 41.

The sensor chip 20 is stacked on the ASIC chip 30 via a first Die Attach Film (DAF) 42. In other words, the sensor chip 20 and the ASIC chip 30 have a stacked structure in which the sensor chip 20 is stacked on the ASIC chip 30.

The sensor chip 20 and the ASIC chip 30 are electrically connected via a plurality of first bonding wires 43. The ASIC chip 30 and the plurality of leads 41 are electrically connected via a plurality of second bonding wires 44.

The ASIC chip 30 and the sensor chip 20 stacked thereon, the plurality of first bonding wires 43, the plurality of second bonding wires 44, and the plurality of lead terminals 41 are encapsulated by the mold resin 40 forming an example of an encapsulating member, to form a sensor package. This sensor package is often referred to as a Plating Lead Package (PLP).

As will be described later in more detail, a second DAF 45 that is used when forming the PLP, remains on a lower surface of the ASIC chip 30. The second DAF 45 has a function to electrically insulate the lower surface of the ASIC chip 30. The second DAF 45 and the plurality of lead terminals 41 are exposed at a lower surface of the humidity sensor 10.

Each lead terminal 41 is made of nickel (Ni) or copper (Cu), for example. The first DAF 42 and the second DAF 45 are made of an insulating material that is a mixture of a resin, silica, or the like, for example. The mold resin 40 is made of an opaque black resin, such as an epoxy resin including a mixture of carbon black, silica, or the like, for example.

An opening 50 is formed on an upper surface side of the humidity sensor 10, to expose a part of the sensor chip 20 from the mold resin 40. This opening 50 is formed by a tapered wall, such that an opening area decreases toward the lower surface of the humidity sensor 10. A lowermost part of this opening 50, that actually exposes the sensor chip 20, will be referred to as an effective opening 51.

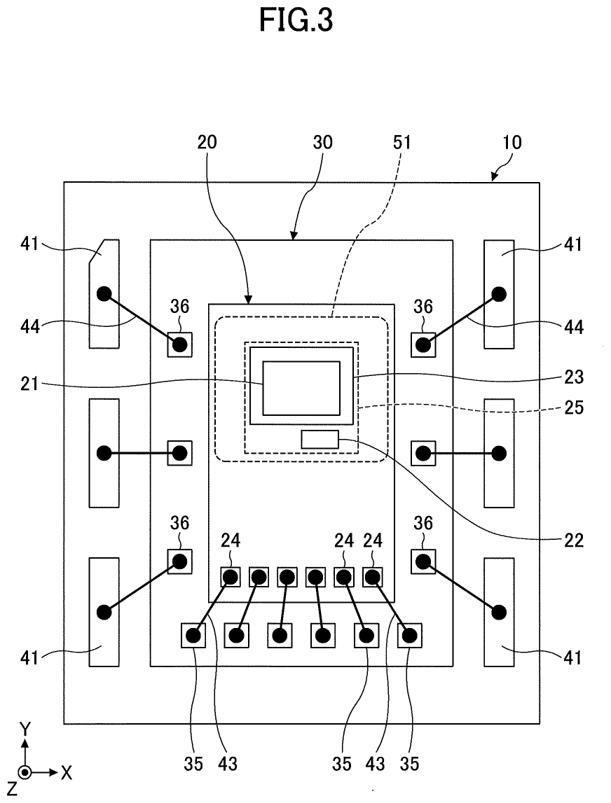

FIG. 3 is a plan view illustrating the humidity sensor 10 in a state where the mold resin 40 is removed. As illustrated in FIG. 3, each of the sensor chip 20 and the ASIC chip 30 has a planar shape that is an approximately rectangular shape having a first pair of opposing sides extending parallel to a X-direction, and a second pair of opposing sides extending parallel to a Y-direction which is perpendicular to the X-direction. The sensor chip 20 is smaller than the ASIC chip 30 in the plan view, and the sensor chip 20 is stacked on the ASIC chip 30 via the first DAF 42.

The sensor chip 20 includes a humidity sensing part 21, a temperature sensing part 22, and a heater part 23 that are provided in a region where these parts 21, 22, and 23 are exposed via the effective opening 51. The heater part 23 is formed on a lower surface side of the humidity sensing part 21, to cover a region where the humidity sensing part 21 is formed. In other words, an area of the heater part 23 is larger than an area of the humidity sensing part 21 in the plan view. Hence, the mold resin 40, forming the example of the encapsulating member, encapsulates the sensor chip 20 or the like in a state where the humidity sensing part 21 and the temperature sensing part 22 are exposed.

In addition, a plurality of bonding pads (hereinafter also referred to as “pads”) 24 are foisted on an end part of the sensor chip 20. In this embodiment, 6 pads 24 are formed. The pads 24 are made of aluminum (Al), aluminum silicon (AlSi) alloys, or the like, for example.

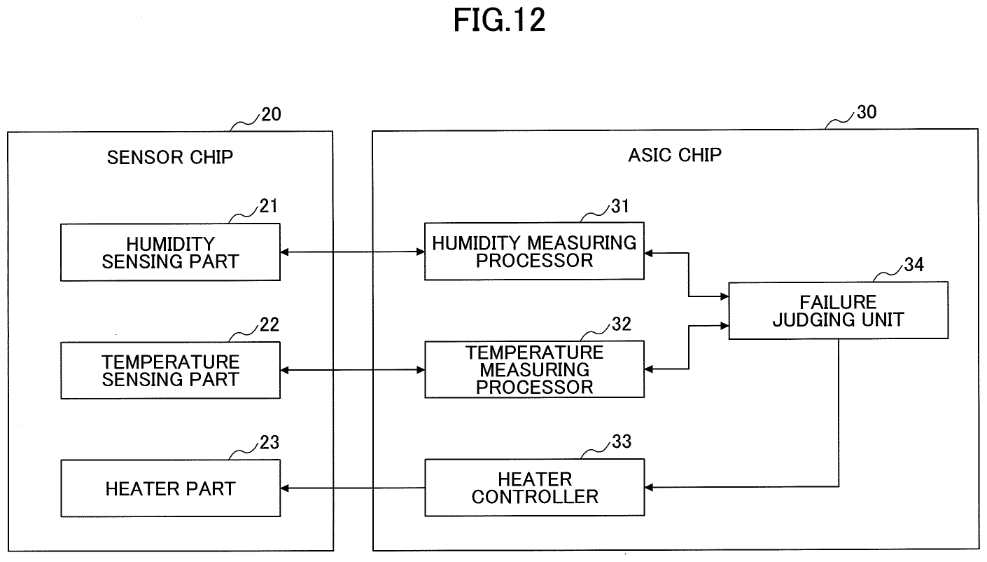

The ASIC chip 30 is a semiconductor chip for signal processing and control. The ASIC chip 30 includes a humidity measuring processor 31, a temperature measuring processor 32, a heater controller 33, and a failure judging unit 34 that are illustrated in FIG. 12 and will be described later.

A plurality of first pads 35, and a plurality of second pads 36 are provided in a region on the surface of the ASIC chip 30 not covered by the sensor chip 20. The first pads 35 and the second pads 36 are made of aluminum (Al), aluminum silicon (AlSi) alloys, or the like, for example.

The first pad 35 is electrically connected to a corresponding pad 24 of the sensor chip 20, via the first bonding wire 43. The second pads 36 is electrically connected to a corresponding lead terminal 41, via the second bonding wire 44. The lead terminals 41 are arranged in a periphery of the ASIC chip 30.

During the manufacturing process of the humidity sensor 10, a mounting position of the ASIC chip 30 is determined with reference to the lead terminals 41. A mounting position of the sensor chip 20 on the ASIC chip 30 is determined with reference to either the position of the ASIC chip 30 or the lead terminals 41. The opening 50 is formed by transfer molding or the like using a mold, and a position of this mold is determined with reference to the lead terminals 41.

A reference numeral “25” illustrated in FIG. 3 indicates a formation tolerable area where the formation of the humidity sensing part 21 and the temperature sensing part 22 on the sensor chip 20 is tolerated. This formation tolerable area 25 is set within a formation region of the opening 50, so as to be positively exposed via the opening 50 even when a maximum positional error occurs among the ASIC chip 30, the sensor chip 20, and the mold during the manufacturing process. The humidity sensing part 21 and the temperature sensing part 22 are positively exposed via the opening 50, regardless of the positional error described above, as long as the humidity sensing part 21 and the temperature sensing part 22 are formed within the formation tolerable area 25.

[Configuration of Sensor Chip]

Next, a configuration of the sensor chip 20 will be described.

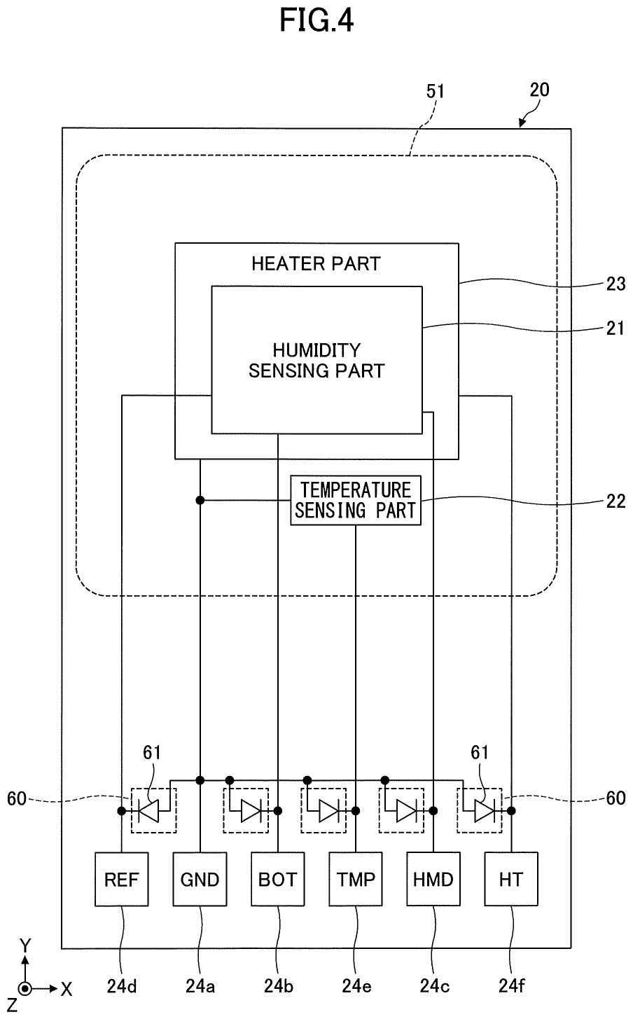

FIG. 4 is a plan view illustrating a general configuration of the sensor chip 20. The plurality of pads 24 described above are terminals used to apply voltages from the outside, terminals used to detect potentials, or the like. In FIG. 4, the plurality of pads 24 are distinguishably illustrated as pads 24a through 24f. The pads 24a through 24f will simply be referred to as “pads 24” in cases where the pads 24a through 24f do not need to be distinguished from one another.

The pad 24a functions as a ground electrode terminal (GND) that is grounded to a ground potential. The pad 24a is electrically connected to various parts of the humidity sensing part 21, the temperature sensing part 22, or the like via interconnects and a substrate.

The pad 24b functions as a lower electrode terminal (BOT) that is electrically connected to a lower electrode 83 of the humidity sensing part 21. The pads 24b is used to supply a driving voltage to the lower electrode 83. The pad 24c functions as a humidity sensing terminal (HMD) that is electrically connected to an upper electrode 84 of the humidity sensing part 21. The pad 24c is used to acquire a relative humidity detection signal from the upper electrode 84. The pad 24d functions as a reference electrode terminal (REF) that is electrically connected to a reference electrode 82 of the humidity sensing part 21. The pad 24d is used to acquire a reference signal for humidity detection, from the reference electrode 82.

The pad 24e functions as a temperature sensing terminal (TMP) that is electrically connected to the temperature sensing part 22. The pad 24e is used to acquire a temperature detection signal. The pad 24f functions as a heater terminal (HT) that is electrically connected to the heater part 23. The pad 24f is used to supply a driving voltage that drives the heater part 23.

An Electro-Static Discharge (ESD) protection circuit 60 is connected to each of the pads 24b through 24f, other than the pad 24a. Each ESD protection circuit 60 is electrically connected between the pad 24a that functions as the ground electrode terminal (GND) and a corresponding one of the pads 24b through 24f used as an input terminal or an output terminal. In this embodiment, the ESD protection circuit 60 includes a single diode 61. The diode 61 has an anode thereof connected to the pad 24a, and a cathode thereof connected to the corresponding one of the pads 24b through 24f.

The ESD protection circuits 60 are preferably arranged near the pads 24b through 24f, so as to be separated as much as possible from the effective opening 51. Because the ESD protection circuits 60 are covered by the mold resin 40, unwanted charges will not be generated due to photoelectric effects.

[Configuration of ESD Protection Circuit]

Next, a configuration of the ESD protection circuit 60 will be described.

FIG. 5 is a circuit diagram illustrating an example of a configuration of the ESD protection circuit 60. As illustrated in FIG. 5, the diode 61 of the ESD protection circuit 60 is formed by an N-channel Metal-Oxide-Semiconductor (MOS) transistor (hereinafter also referred to as an “NMOS transistor”. More particularly, the diode 61 is formed by the NMOS transistor having a source, a gate, and a back gate thereof that are short-circuited to form the so-called diode connection. The short-circuited part of the NMOS transistor functions as an anode of the diode 61, and a drain of the NMOS transistor functions as a cathode of the diode 61.

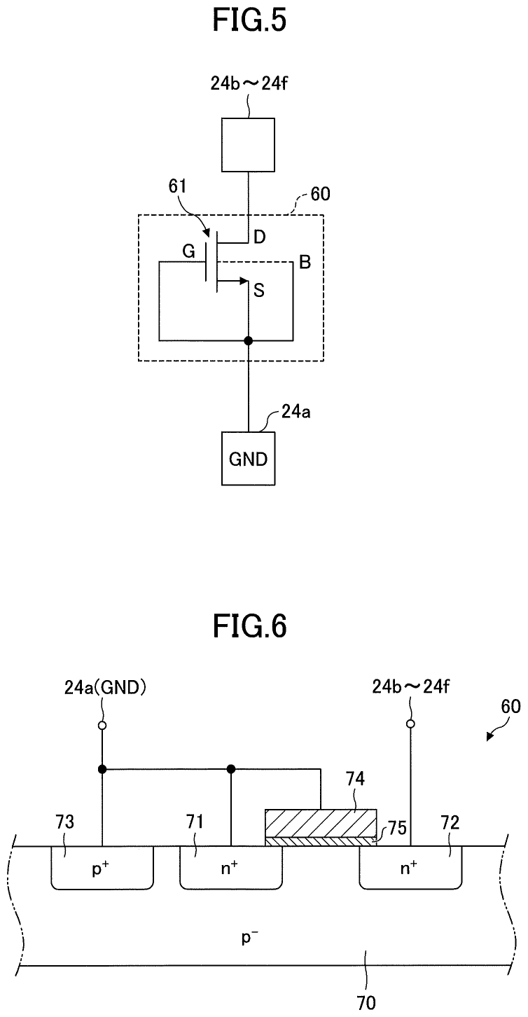

FIG. 6 is a diagram illustrating a layer structure of the NMOS transistor forming the ESD protection circuit 60. The NMOS transistor illustrated in FIG. 6 includes a p-type semiconductor substrate 70, 2 n-type diffusion layers 71 and 72 formed at the surface of the p-type semiconductor substrate 70, a contact layer 73, and a gate electrode 74. The gate electrode 74 is formed on the surface of the p-type semiconductor substrate 70 via a gate insulating layer 75. The gate electrode 74 is arranged between the 2 n-type diffusion layers 71 and 72.

For example, the n-type diffusion layer 71 functions as the source, and the n-type diffusion layer 72 functions as the drain. The contact layer 73 is a low-resistance layer (or p-type diffusion layer) for making electrical connection to the p-type semiconductor substrate 70, to function as the back gate. The n-type diffusion layer 71, the gate electrode 74, and the contact layer 73 are connected in common and short-circuited. This short-circuited part functions as the anode, and the n-type diffusion layer 72 functions as the cathode.

The p-type semiconductor substrate 70 is a p-type silicon (Si) substrate, for example. The gate electrode 74 is made of a metal, polysilicon, or the like, for example. The gate insulating layer 75 is an oxide layer made of silicon oxide or the like, for example.

[Configuration of Humidity Sensing Part]

Next, a configuration of the humidity sensing part 21 will be described.

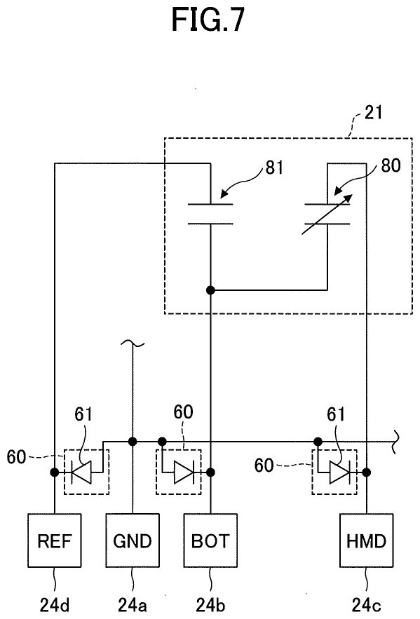

FIG. 7 is a circuit diagram illustrating an example of the configuration of the humidity sensing part 21. As illustrated in FIG. 7, the humidity sensing part 21 includes a humidity sensing capacitor 80, and a reference capacitor 81.

The lower electrode (first electrode) 83 of the humidity sensing part 21 is electrically connected to the pad 24b that functions as the lower electrode terminal. The upper electrode (second electrode) 84 of the humidity sending part 21 is electrically connected to the pad 24c that functions as the humidity sensing terminal. One electrode of the reference capacitor 81 is provided in common as the lower electrode 83. The other electrode of the reference capacitor 81 is electrically connected to the pad 24d that functions as the reference electrode terminal.

The humidity sensing layer 86 that will be described later is provided between the electrodes of the humidity sensing capacitor 80. The humidity sensing layer 86 is made of a polymer material, such as polyimide or the like, that adsorbs moisture in air, and whose dielectric constant varies according to the adsorbed moisture content. Accordingly, an electrostatic capacitance of the humidity sensing capacitor 80 varies according to the moisture content adsorbed by the humidity sensing layer 86.

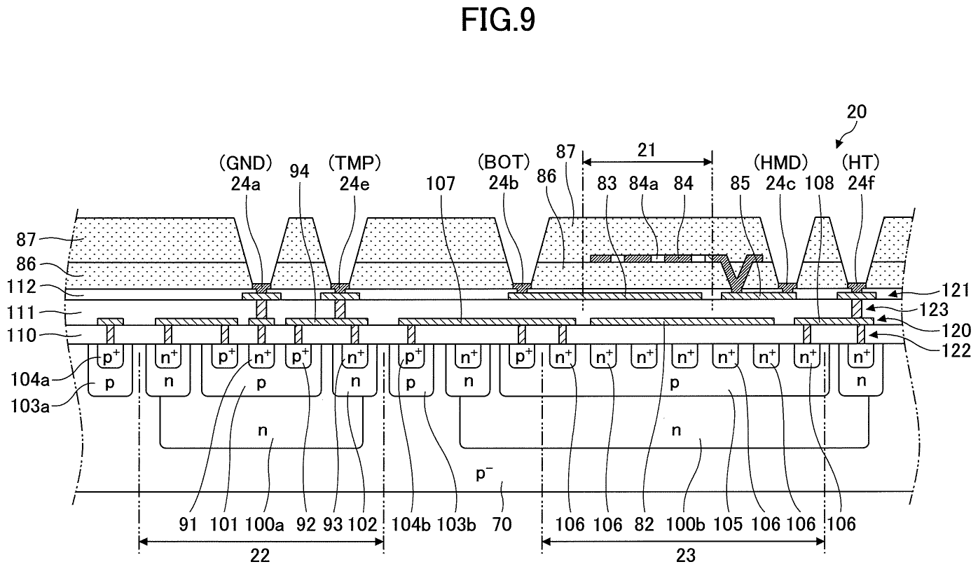

A second insulating layer 111 illustrated in FIG. 9 is provided between the electrodes of the reference capacitor 81. The second insulating layer 111 is made of an insulating material, such as silicon dioxide (SiO₂) or the like, that does not adsorb moisture. Accordingly, the electrostatic capacitance of the reference capacitor 81 does not vary, or varies only slightly.

The moisture content included in the moisture sensing layer 86 corresponds to an ambient humidity of the humidity sensor 10. Hence, the relative humidity can be measured by detecting a difference between the electrostatic capacitance of the humidity sensing capacitor 80 and the electrostatic capacitance of the reference capacitor 81. This measurement of the relative humidity is performed by the humidity measuring processor 31 illustrated in FIG. 12 inside the ASIC chip 30, based on the potential of the pad 24c that functions as the humidity sensing terminal, and the potential of the pad 24d that functions as the reference electrode terminal.

[Configuration of Temperature Sending Part]

Next, a configuration of the temperature sensing part 22 will be described.

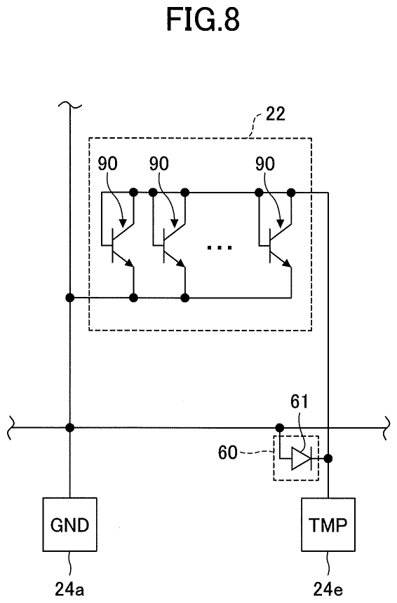

FIG. 8 is a circuit diagram illustrating an example of the configuration of the temperature sensing part 22. The temperature sensing part 22 has a band-gap structure that senses the temperature utilizing the electrical characteristic of the semiconductor that varies proportionally to a temperature change at the band-gap. For example, the temperature sensing part 22 includes one or a plurality of 2-terminal bipolar transistors having 2 of the base, emitter, and collector that are connected. The temperature can be measured by sensing the resistance between the 2 terminals of the one or plurality of bipolar transistors.

As illustrated in FIG. 8, the temperature sensing part 22 in this embodiment is formed by a plurality of (8 in this example) npn type bipolar transistors 90 respectively having the base and collector that are connected, connected in parallel. By connecting the plurality of bipolar transistors 90 in parallel, a junction area of the pn junction can be made large, to improve the ESD resistance.

The emitter of the plurality of bipolar transistors 90 is electrically connected to the pad 24a that functions as the ground electrode terminal. The base and the collector of the plurality of bipolar transistors 90 are electrically connected to the pad 24e that functions as the temperature sensing terminal.

The temperature measurement is performed by the temperature measuring processor 32 illustrated in FIG. 12 inside the ASIC chip 30, based on the potential of the pad 24e.

[Device Structure of Sensor Chip]

Next, a device structure of the sensor chip 20 will be described.

FIG. 9 is a cross sectional view for explaining the device structure of the sensor chip 20. For the sake of convenience to facilitate understanding of the device structure, FIG. 9 illustrates the pads 24a, 24b, 24c, and 24e within the same cross section as the humidity sensing part 21, the temperature sensing part 22, and the heater part 23, however, these pads and parts do not actually exist within the same cross section. Further, the cross section of the humidity sensing part 21, the temperature sensing part 22, and the heater part 23 are also simplified in FIG. 9 to facilitate the understanding of the device structure, however, the actual positional relationships of these parts in the cross section are different from that illustrated in FIG. 9.

As illustrated in FIG. 9, the sensor chip 20 is formed using the p-type semiconductor substrate 70 described above. A first deep n-well 100a, and a second deep n-well 100b are formed in the p-type semiconductor substrate 70. The temperature sensing part 22 is formed in the first deep n-well 100a, and the heater part 23 is formed in the second deep n-well 100b.

P-wells 103a and 103b are formed at the surface of the p-type semiconductor substrate 70 where neither the first deep n-well 100a nor the second deep n-well 100b is formed. Contact layers 104a and 104b, made of p-type diffusion regions, are formed at the surface of the p-wells 103a and 103b, respectively. The contact layers 104a and 104b are low-resistance layers (p-type diffusion layers) for making electrical connections between the p-type semiconductor substrate 70 and predetermined interconnect layers formed on the p-type semiconductor substrate 70.

A p-well 101 and an n-well 102 are formed at the surface of the first deep n-well 100a. An n-type diffusion layer 91 and a p-type diffusion layer 92 are formed at the surface of the p-well 101. An n-type diffusion layer 93 is formed at the surface of the n-well 102. The n-type diffusion layer 91, the p-type diffusion layer 92, and the n-type diffusion layer 93 form the npn-type bipolar transistor 90 described above, and function as the emitter, base, and collector, respectively.

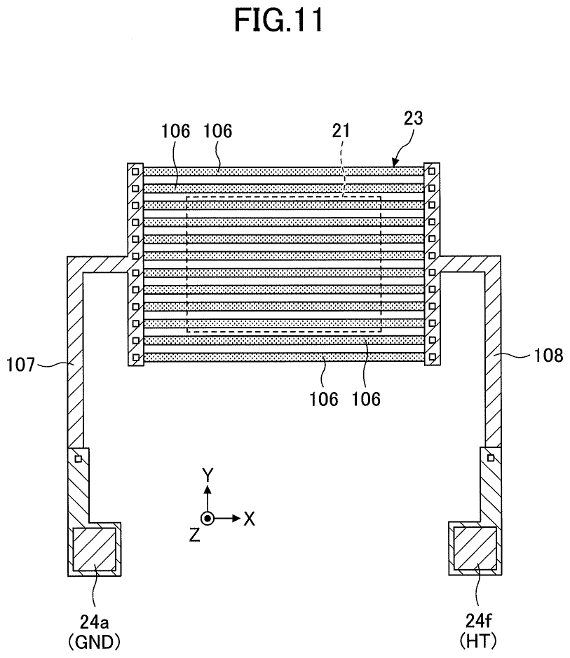

A p-well 105 is formed at the surface of the second deep n-well 100b. One or a plurality of n-type diffusion layers 106 are formed at the surface of the p-well 105. A plurality of n-type diffusion layers 106 are formed in this embodiment. For example, each n-type diffusion layer 106 extends in a direction perpendicular to the paper surface of FIG. 9, and forms a one-dimensional lattice as a whole, as illustrated in FIG. 11.

The n-type diffusion layer 106 has a predetermined resistance (for example, a sheet resistance of approximately 3Ω), and functions as a resistor that generates heat when a current flows through the resistor. In other words, the n-type diffusion layer 106 forms the heater part 23 described above.

Each layer of the p-type semiconductor substrate 70 is formed using an existing semiconductor manufacturing process (CMOS process). Accordingly, the n-type diffusion layer 106 that functions as the heat-generating resistor is formed by the same manufacturing process used to form the n-type diffusion layers 91 and 93 included in a part of the temperature sensing part 22. In other words, a depth of the n-type diffusion layer 106 that functions as the heat-generating resistor, from the surface of the p-type semiconductor substrate 70, is the same as the depths of the n-type diffusion layers 91 and 93 included in the part of the temperature sensing part 22. In addition, the depth of the n-type diffusion layer 106, from the surface of the p-type semiconductor substrate 70, may be the same as the depth of the p-type diffusion layer 92 included in a part of the temperature sensing part 22.

The n-type diffusion layers 106, 91, and 93 may be formed simultaneously by an ion implantation process that adds impurities to the p-type semiconductor substrate 70, by implanting n-type impurities such as phosphorus (P) into the p-type semiconductor substrate 70. The n-type diffusion layers 106, 91, and 93 may also be formed by a thermal diffusion process that adds impurities to the p-type semiconductor substrate 70 by a thermal process, in place of employing the ion implantation process.

In addition, the n-type diffusion layers 71 and 72 of the ESD protection circuit 60 described above may also be formed by the same manufacturing process (ion implantation process or thermal diffusion process) employed to form the n-type diffusion layers 106, 91, and 93. The contact layer 73 may be formed by the same manufacturing process (ion implantation process or thermal diffusion process) employed to form the p-type diffusion layer 92 and the contact layers 104a and 104b.

Other layers of the p-type semiconductor substrate 70 mainly function as contact layers, and thus, a description thereof will be omitted.

A first insulating layer 110, the second insulating layer 111, and a third insulating layer 112 are successively stacked on the surface of the p-type semiconductor substrate 70. These insulating layers 110, 111, and 112 are made of an insulating material, such as silicon dioxide (SiO₂), silicon nitride (SiN), or the like, for example.

A first interconnect layer 120 is formed on the first insulating layer 110. A second interconnect layer 121 is formed on the second insulating layer 111. The second insulating layer 111 covers the first interconnect layer 120. The third insulating layer 112 covers the second interconnect layer 121. The first interconnect layer 120 and the second interconnect layer 121 are made of a conductive material, such as aluminum (Al) or the like, for example.

A first plug layer 122, having a plurality of first plugs for electrically connecting the first interconnect layer 120 to the p-type semiconductor substrate 70, is formed in the first insulating layer 110. A second plug layer 123, having a plurality of second plugs for electrically connecting the first interconnect layer 120 to the second interconnect layer 121, is formed in the second insulating layer 111. The first plug layer 122 and the second plug layer 123 are made of a conductive material, such as tungsten (W) or the like, for example.

For example, an interconnect 94 for connecting the base and the collector of the bipolar transistor 90 described above, is formed by the first interconnect layer 120, and is electrically connected to the p-type diffusion layer 92 and the n-type diffusion layer 93 via the first plug layer 122. In addition, the interconnect 94 is electrically connected to the pad 24e that functions as the temperature sensing terminal, via the second plug layer 123 and the second interconnect layer 121. Further, the n-type diffusion layer 91, forming the emitter of the bipolar transistor 90, is electrically connected to the pad 24a that functions as the ground electrode terminal, via the first plug layer 122, the first interconnect layer 120, and the second interconnect layer 121.

An interconnect 107 for grounding one end of the heater part 23 to the ground potential, is formed by the first interconnect layer 120, and is electrically connected to the n-type diffusion layer 106 and the contact layer 104b via the first plug layer 122. In addition, an interconnect 108 for electrically connecting the other end of the heater part 23 to the pad 24f that functions as the heater terminal, is electrically connected to the n-type diffusion layer 106 via the first plug layer 122, and is electrically connected to the pad 24f via the second plug layer 123 and the second interconnect layer 121. The interconnect 108 preferably has a width that is wider than other interconnects, in order to prevent electromigration caused by a large current flowing through the heater part 23.

The reference electrode 82 of the reference capacitor 81 is formed by the first interconnect layer 120, and is electrically connected to the pad 24d (not illustrated in FIG. 9) that functions as the reference electrode terminal, via the second plug layer 123 and the second interconnect layer 121.

In addition, the lower electrode 83 of the humidity sensing capacitor 80 is formed by the second interconnect layer 121, and is electrically connected to the pad 24b that functions as the lower electrode terminal. Moreover, an interconnect 85 for electrically connecting the upper electrode 84 of the humidity sensing capacitor 80 to the pad 24c that functions as the humidity sensing terminal, is formed by the second interconnect layer 121. The lower electrode 83 is arranged at a position opposing the reference electrode 82 via the second insulating layer 111.

The pads 24a through 24f are formed on the third insulating layer 112 by a conductive material, such as aluminum (Al) or the like, and are electrically connected to the second interconnect layer 121 by penetrating the third insulating layer 112.

The humidity sensing layer 86 is formed on the third insulating layer 112. The humidity sensing layer 86 has a thickness of 0.5 μm to 1.5 μm, and is made of a polymer material that enables easy adsorption and easy desorption of water molecules to and from the polymer material depending on the humidity. The humidity sensing layer 86 may be a polyimide layer having a thickness of 1 μm, for example. The polymer material forming the humidity sensing layer 86 is not limited to polyimide, and may be cellulose, polymethyl methacrylate (PMMA), polyvinyl alcohol (PVA), or the like.

The humidity sensing layer 86 has a flat upper surface, and the plate-shaped upper electrode 84 is formed on this upper surface of the humidity sensing layer 86. The upper electrode 84 is formed at a position opposing the lower electrode 83 via the humidity sensing layer 86. A part of the upper electrode 84 is electrically connected to the interconnect 85. The upper electrode 84 is a conductive layer made of aluminum (Al) or the like and having a thickness of 200 nm, for example. The upper electrode 84 includes a plurality of holes 84a, so that the water molecules in air can be efficiently adsorbed by the humidity sensing layer 86.

An overcoat layer 87 is formed on the humidity sensing layer 86, to cover the upper electrode 84. The overcoat layer 87 is made of a polymer material that is the same as the polymer material of the humidity sensing layer 86, for example. The overcoat layer 87 has a thickness of 0.5 μm to 10 μm, for example.

Holes are formed in the humidity sensing layer 86 and the overcoat layer 87, to expose the pads 24a through 24f.

Hence, the humidity sensing capacitor 80, which is a parallel plate type, is formed by the lower electrode 83 and the upper electrode 84. In addition, the reference capacitor 81, which is a parallel plate type, is formed by the lower electrode 83 and the reference electrode 82. Further, the humidity sensing capacitor 80 and the reference capacitor 81 are arranged above the heater part 23.

Accordingly, the humidity sensing layer 86 between the lower electrode 83 and the upper electrode 84 is heated when the heater part 23 generates heat. As the temperature of the humidity sensing layer 86 rises by being heated, the humidity sensing layer 86 adsorbs an amount of water molecules according to the humidity, to vary the dielectric constant of the humidity sensing layer 86, and lower the electrostatic capacitance of the humidity sensing capacitor 80. In addition, the temperature sensing part 22 senses a temperature rise caused by the heater part 23.

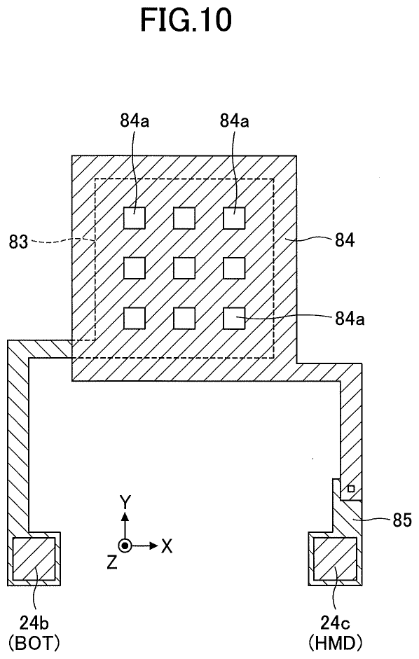

FIG. 10 is a plan view illustrating an example of shapes of the lower electrode 83 and the upper electrode 84. As illustrated in FIG. 10, the lower electrode 83 and the upper electrode 84 both have a rectangular shape. The upper electrode 84 is formed over the lower electrode 83 to cover the lower electrode 83.

The plurality of holes 84a are preferably as small as possible, because the smaller the holes 84a are, the more positively a leak of the electric field to the air can be prevented. Actually, a large number of holes 84a are formed. The holes 84a are not limited to a square shape, and may have an elongated stipe shape, a circular shape, or the like. In addition, the holes 84a may be arranged in a staggered pattern. Preferably, the holes 84a have the circular shape, and are arranged in the staggered pattern.

The rectangular reference electrode 82 is formed below the lower electrode 83, although the illustration thereof is omitted in FIG. 10.

FIG. 11 is a plan view illustrating an example of the n-type diffusion layer 106 forming the heater part 23. As illustrated in FIG. 11, the n-type diffusion region 106 has a one-dimensional lattice shape including a plurality of elongated stripe-shaped regions that are arranged in parallel. One end of the n-type diffusion layer 106 having the one-dimensional lattice shape is electrically connected to the interconnect 107 described above, and the other end of the n-type diffusion layer 106 is electrically connected to the interconnect 108 described above. The heater part 23 is arranged below the temperature sensing part 22, so as to cover the entire humidity sensing part 21.

[Functional Structure of ASIC Chip]

Next, functional parts of the ASIC chip 30 will be described.

FIG. 12 is a block diagram illustrating an example of a functional configuration of the ASIC chip 30. As illustrated in FIG. 12, The ASIC chip 30 includes the humidity measuring processor 31, the temperature measuring processor 32, the heater controller 33, and the failure judging unit 34.

The humidity measuring processor 31 applies a predetermined driving voltage to the pad 24b that functions as the lower electrode terminal, and detects the potential of the pad 24c that functions as the humidity sensing terminal and the potential of the pad 24d that functions as the reference electrode terminal. The humidity measuring processor 31 performs a signal processing based on a difference (or potential difference) between the detected potentials, to compute the relative humidity (% RH).

The temperature measuring processor 32 detects the potential of the pad 24e that functions as the temperature sensing terminal, and computes the temperature corresponding to the detected potential.

The heater controller 33 applies a predetermined driving voltage to the pad 24f that functions as the heater terminal, and applies a current (for example, approximately 10 mA) to the heater part 23, to generate heat from the heater part 23. The heater controller 33 controls the amount of heat generated from the heater part 23, by controlling the predetermined driving voltage applied to the pad 24f.

The failure judging unit 34 judges whether a failure occurred, based on the relative humidity measured by the humidity measuring processor 31, and the temperature measured by the temperature measuring processor 32. The failure judging unit 34 outputs an instruction related to a start and an end of the heating by the heater part 23 when judging the failure. More particularly, the failure judging unit 34 judges the occurrence of the failure in a case where the temperature does not rise after generating heat from the heater part 23, and also in a case where the temperature rises but the humidity does not decrease.

[Position where Opening is Formed]

Next, a position where the opening 50 is formed during the manufacturing process of the humidity sensor 10, in order to reduce deterioration of the yield caused by forming the opening 50, will be described.

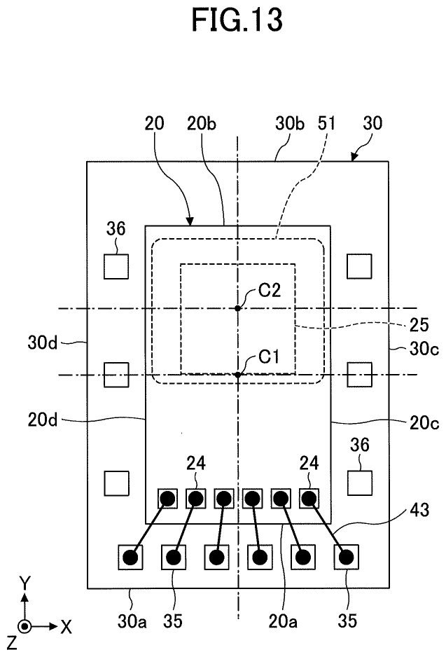

FIG. 13 is a diagram for explaining the position where the opening 50 is formed.

In this embodiment, the sensor chip 20 has a planar shape that is an approximately rectangular shape having a first pair of opposing sides 20a and 20b extending parallel to the X-direction, and a second pair of opposing sides 20c and 20d extending parallel to the Y-direction which is perpendicular to the X-direction. The sides 20a and 20b are shorter sides of the rectangular shape, opposing each other along the Y-direction. The sides 20c and 20d are longer sides of the rectangular shape, opposing each other along the X-direction.

Similarly, the ASIC chip 30 has a planar shape that is an approximately rectangular shape having a first pair of opposing sides 30a and 30b extending parallel to the X-direction, and a second pair of opposing sides 30c and 30d extending parallel to the Y-direction which is perpendicular to the X-direction. The sides 30a and 30b are shorter sides of the rectangular shape, opposing each other along the Y-direction. The sides 30c and 30d are longer sides of the rectangular shape, opposing each other along the X-direction.

The first pair of opposing sides 20a and 20b of the sensor chip 20 are parallel to the first pair of opposing sides 30a and 30b of the ASIC chip 30. The second pair of opposing sides 20c and 20d of the sensor chip 20 are parallel to the second pair of opposing sides 30c and 30d of the ASIC chip 30.

In the sensor chip 20, the plurality of pads 24 are arranged along the side 20a of the sensor chip 20. In the ASIC chip 30, the plurality of first pads 35, that are electrically connected to the plurality of pads 24 via the plurality of first bonding wires 43, are arranged along the side 30a of the ASIC chip 30.

A center position of the sensor chip 20 is denoted by C1, and a center position of the opening 50 is denoted by C2. The center position C2 of the opening 50 is arranged at a position closer to the side 20b than the center position C1 of the sensor chip 20. The plurality of pads 24 are not arranged along the side 20b of the sensor chip 20.

In addition, the center position C2 of the opening 50 is preferably located on an imaginary straight line parallel to the Y-direction and passing through the center position C1 of the sensor chip 20.

Further, the center position C1 of the sensor chip 20 is preferably located within the opening 50.

Preferably, the opening 50 is arranged on the sensor chip 20, and has a size to expose the formation tolerable area 25 of the humidity sensing part 21 and the temperature sensing part 22.

[Method of Manufacturing Humidity Sensor]

Next, a method of manufacturing the humidity sensor 10 will be described.

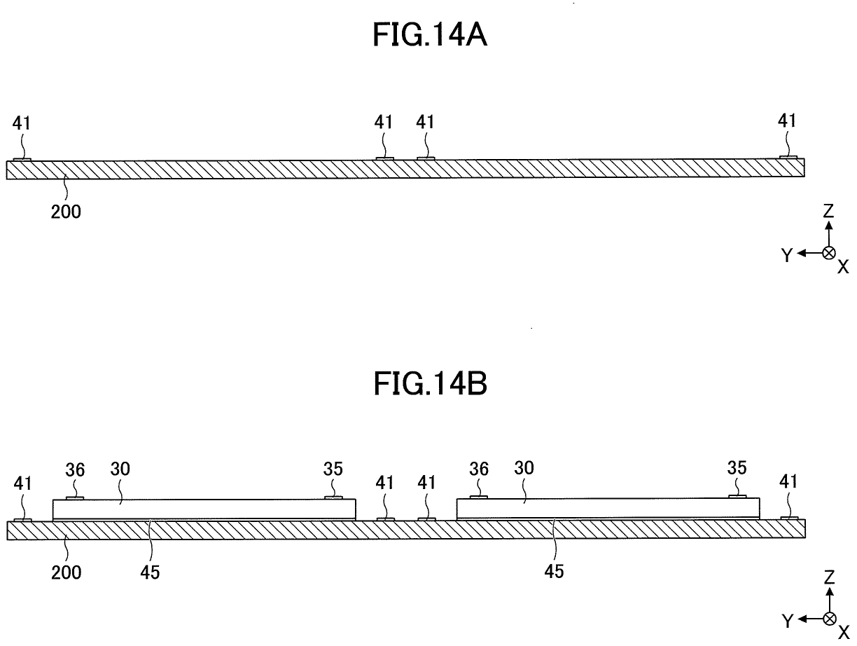

FIG. 14A through FIG. 17B are diagrams for explaining an example of manufacturing processes of the humidity sensor 10. FIG. 14A through FIG. 17B illustrate cross sections along the YZ-plane.

First, as illustrated in FIG. 14A, the lead terminals 41 are formed on a plate 200 by electrocasting or the like, using nickel (Ni), copper (Cu), or the like, for example. The plate 200 is made of stainless steel, for example.

Next, as illustrated in FIG. 14B, a plurality of ASIC chips 30 manufactured using the semiconductor manufacturing process are fixed on the surface of the plate 200 via the second DAF 45. Although a large number of ASIC chips 30 are actually fixed on the plate 200, only 2 ASIC chips 30 are illustrated in FIG. 14B for the sake of convenience to simplify the drawing.

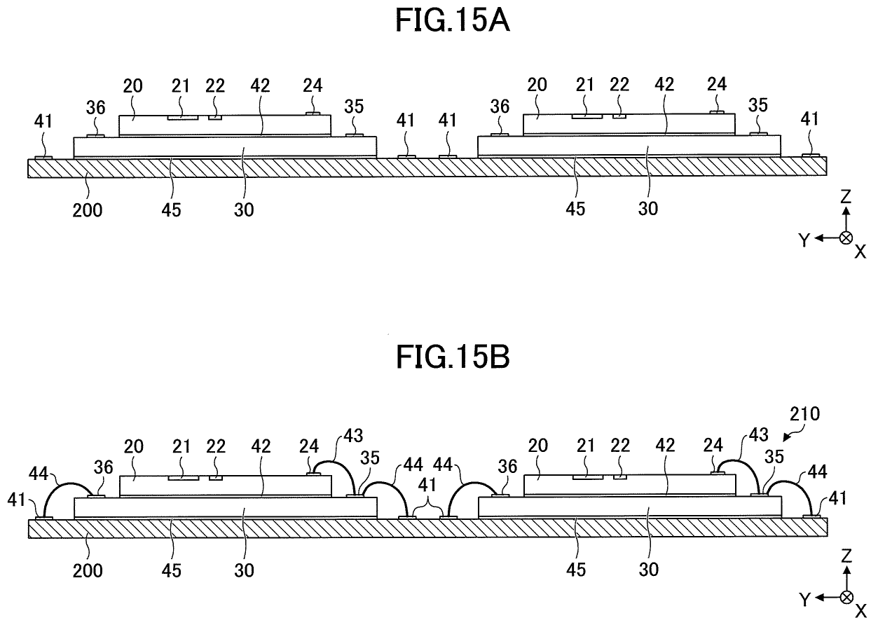

Next, as illustrated in FIG. 15A, the sensor chip 20 manufactured using the semiconductor manufacturing process is fixed on the surface of each ASIC chip 30 via the first DAF 42.

Then, as illustrated in FIG. 15B, the second pads 36 on each ASIC chip 30 are electrically connected to the lead terminals 41 via the second bonding wires 44, and the pads 24 on each sensor chip 20 that is mounted on the ASIC chip 30 and the first pads 35 on this ASIC chip 30 are electrically connected via the first bonding wires 43. The structure illustrated in FIG. 15B will hereinafter be referred to a component 210.

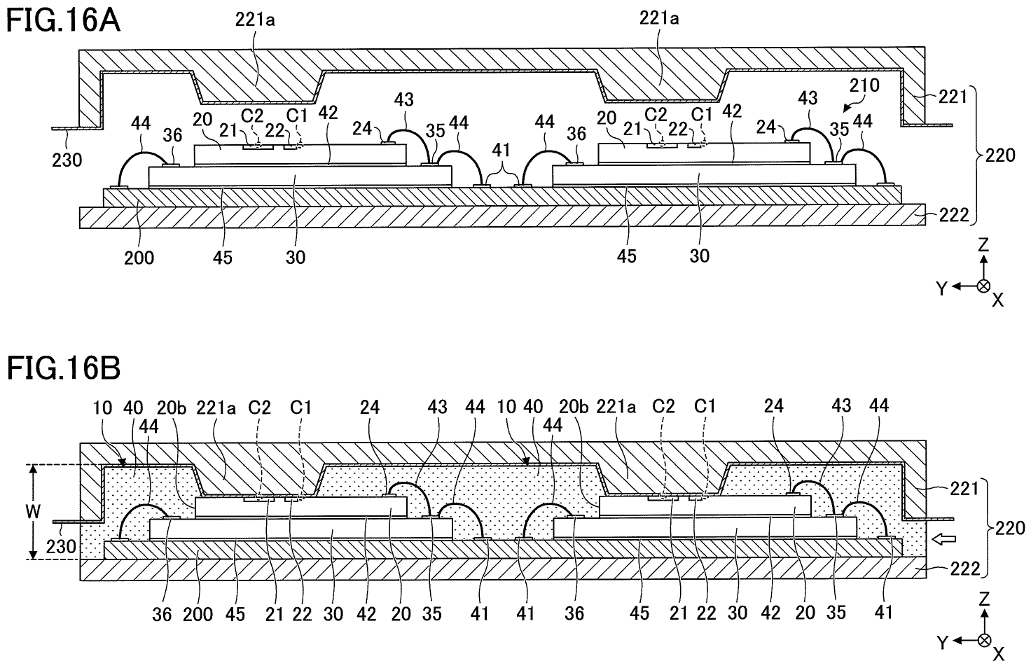

Next, as illustrated in FIG. 16A, a mold 220 made up of an upper mold 221 and a lower mold 222 is prepared, and the component 210 is placed on the lower mold 222.

The mold 220 is for the resin encapsulation using the transfer molding. The upper mold 221 includes a plurality of projections 221a for forming the openings 50 in the mold resin 40 described above. Each projection 221a has a trapezoidal cross section.

A release film 230 has an area covering the entire inner surface of the upper mold 221, and is flexible so that the release film 230 deforms according to the concavo-convex inner surface of the upper mold 221. In addition, the release film 230 is sufficiently heat resistant to withstand the heating temperature at the time of molding the resin, and has a mold release characteristic that enables the release film 230 to easy separate from the mold resin 40 and the mold 220. The release film 230 is made of ethylene-tetrafluoroethylene ETFE) or the like, for example.

Next, as illustrated in FIG. 16B, the upper mold 221 is connected to the lower mold 222 via the release film 230. In this state, a positional adjustment is made so that a tip end surface of each projection 221a contacts the formation region of the opening 50 at the surface of the sensor chip 20. More particularly, the positional adjustment of the projection 221a is made so that the center position C2 of the opening 50 that is formed by the projection 221a is arranged at a position closer to the side 20b than the center position C1 of the sensor chip 20, and the center position C1 is included in the formation region of the opening 50.

A thickness T1 of the sensor chip 20 (illustrated in FIG. 2) and a thickness T2 of the ASIC chip 30 (illustrated in FIG. 2) are preferably set to 200 μm or greater, respectively, so as to prevent the sensor chip 20 and the ASIC chip 30 from being pressed by the upper mold 221 and becoming damaged due to stress when the upper mold 221 and the lower mold 222 are connected via the release film 230.

A height W of the internal space of the mold 220 is set so that the upper mold 221 does not make contact with the first bonding wires 43 and the second bonding wires 44.

The mold 220 is heated in the state where the upper mold 221 and the lower mold 222 are connected and closed via the release film 230. In addition, the mold resin 40 is supplied to the internal space of the mold 220, via a supply passage as indicated by an arrow in FIG. 16B. As a result, the sensor chips 20, the ASIC chips 30, the first bonding wires 43, the second bonding wires 44, and the lead terminals 41 are encapsulated by the mold resin 40.

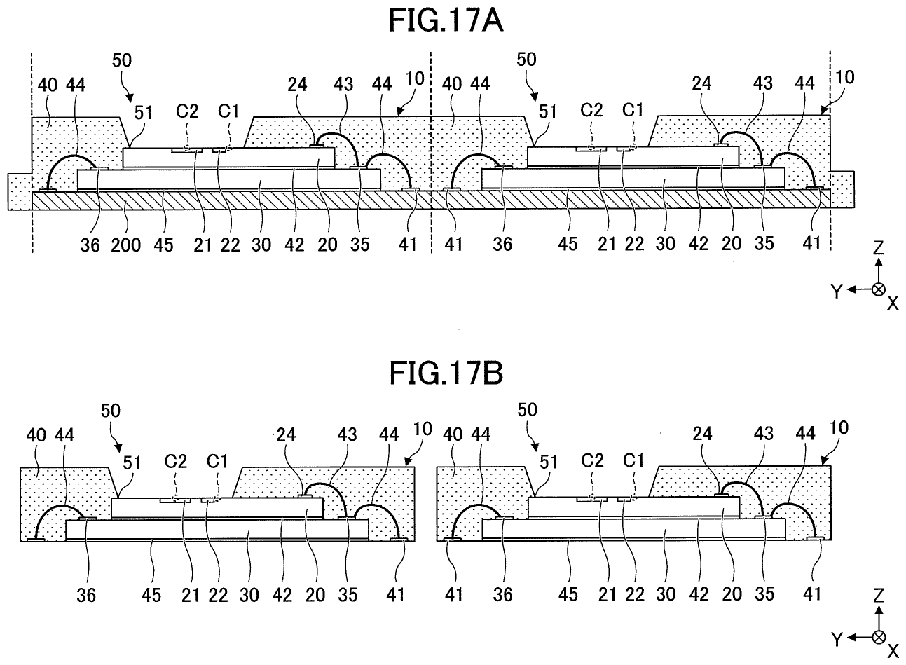

As illustrated in FIG. 17A, after the mold resin 40 solidifies (or cures), the upper mold 221 is separated from the lower mold 222, the humidity sensors 10 are extracted from the lower mold 222, and the release film 230 is separated from the humidity sensor 10. In this state, the opening 50 is formed in the mold resin 40 of each humidity sensor 10, by the projection 221a of the upper mold 221.

After scribing the mold resin 40 and the plate 200 at a boundary of the humidity sensors 10 indicated by a dotted line in FIG. 17A, the plate 200 is removed, to complete the plurality of individual humidity sensors 10 illustrated in FIG. 17B.

As in the manufacturing process described above, the connection of the first bonding wires 43 and the connection of the second bonding wires 44 are preferably made after fixing the ASIC chips 30 and the sensor chips 20 on the plate 200 as illustrated in FIG. 15A. However, the connection of the second bonding wires 44 may be made immediately after fixing the ASIC chips 30 on the plate 200 as illustrated in FIG. 14B.

[Advantageous Features]

According to the method of manufacturing the humidity sensor 10 described above, the sensor chip 20 is mounted with reference to the ASIC chip 30, the ASIC chip 30 is mounted with reference to the plate 200, and the mold 220 is mounted on the component 210 with reference to the plate 200. For this reason, an error may be generated in the position where the opening 50 is formed, due to mounting error or the like. However, the opening 50 is formed to the size that positively exposes the humidity sensing part 21 and the temperature sensing part 22, even when such an error is generated.

In this embodiment, the center position C2 of the opening 50 is arranged at a position closer to the side 20b, opposite from the side 20a where the pads 24 are arranged, than the center position C1 of the sensor chip 20. Hence, it is possible to prevent the first bonding wires 43 connected to the pads 24 from becoming exposed via the opening 50. As a result, the generation of a defect during the manufacturing process is reduced, to improve the yield during the manufacturing process.

Further, according to this embodiment, the center position C1 of the sensor chip 20 is located within the opening 50, and when forming the opening 50, the region at the surface of the sensor chip 20, including the center position C1, is pressed by the projection 221a. For this reason, damage, such as cracking of the chip or the like, caused by the pressing of the projection 221a, is reduced, to further improve the yield during the manufacturing process.

[Modifications]

Next, modifications of the above-mentioned embodiment will be described.

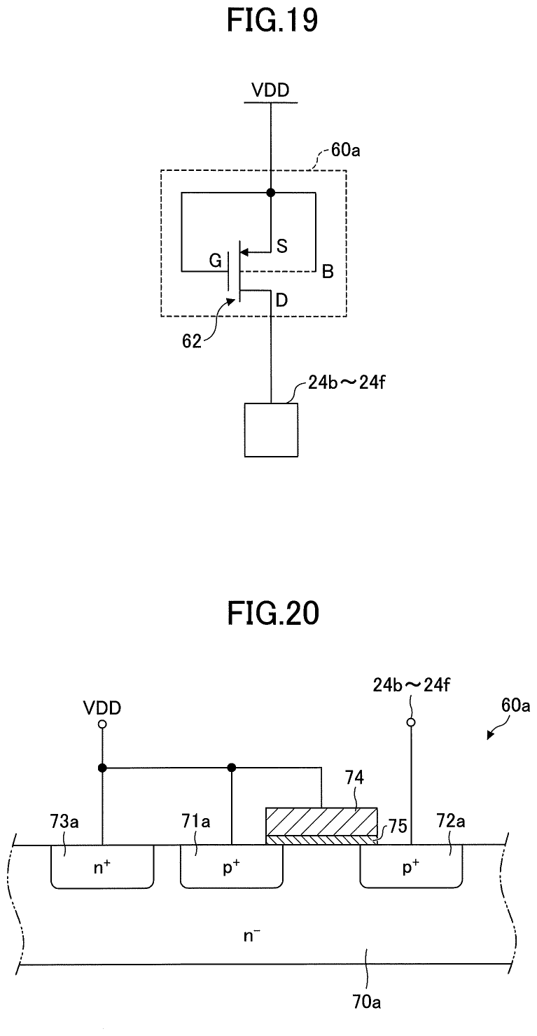

The gate electrode of the NMOS transistor forming the ESD protection circuit 60 according to the embodiment, or the gate electrode of a P-channel MOS transistor (hereinafter also referred to as a “PMOS transistor”) forming an ESD protection circuit 60a according to the modification described later in conjunction with FIG. 19 and FIG. 20, may be formed by a process that is common to the process of forming the interconnect layers of the humidity sensing part 21 and the temperature sensing part 22. In this case, it is possible to simplify the manufacturing process of the sensor chip 20.

In addition, the ESD protection circuit is not limited to the MOS transistor, and may be formed by a pn junction within the semiconductor substrate. In this case, there is no need to form the gate electrode, and it is possible to further simplify the manufacturing process of the sensor chip 20.

In the embodiment described above, the temperature sensing part 22 is formed by the npn type bipolar transistor 90. However, the temperature sensing part 22 may be formed by a pnp type bipolar transistor. In addition, the temperature sensing part 22 may be formed by one or a plurality of pn junction diodes, in place of using the bipolar transistor.

The temperature sensing part 22 may be formed by a temperature sensor having a structure other than the band-gap structure including the pn junction. For example, the temperature sensing part 22 may be formed by a resistance type temperature sensor that uses an impurity diffusion layer (n-type diffusion layer or p-type diffusion layer) as the resistor, and senses the temperature based on the temperature-dependent resistance of the resistor.

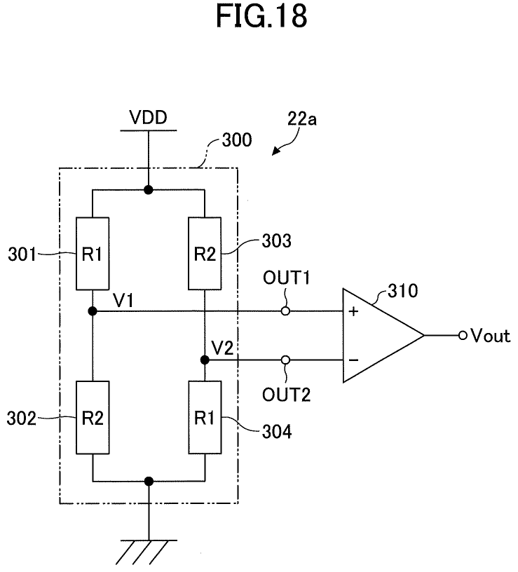

FIG. 18 is a diagram illustrating an example of the temperature sensing part formed by the resistance type temperature sensor. A temperature sensing part 22a illustrated in FIG. 18 includes a bridge circuit 300 including a first resistor 301, a second resistor 302, a third resistor 303, and a fourth resistor 304 that are mutually connected.

The first resistor 301 and the second resistor 302 are connected in series between a power supply potential VDD and the ground potential. Similarly, the third resistor 303 and the fourth resistor 304 are connected in series between the power supply potential VDD and the ground potential.

The first through fourth resistors 301 through 304 are formed by an n-type diffusion layer or a p-type diffusion layer formed at the surface of the semiconductor substrate. The impurity concentrations are approximately the same and the temperature coefficients are approximately the same for the first resistor 301 and the fourth resistor 304. The impurity concentrations are approximately the same and the temperature coefficients are approximately the same for the second resistor 302 and the third resistor 303.

A potential V1 at a node connecting the first resistor 301 and the second resistor 302 is input to a differential amplifier 310 via an external terminal OUT1. A potential V2 at a node connecting the third resistor 303 and the fourth resistor 304 is input to the differential amplifier 310 via an external terminal OUT2. The external terminals OUT1 and OUT2 are formed by 2 pads 24 in place of the temperature sensing terminal described above.

The differential amplifier 310 is provided inside the ASIC chip 30, for example, and amplifies a difference between the potential V1 and the potential V2, to produce a differential output Vout. When the resistance of the first resistor 301 and the fourth resistor 304 is denoted by R1, and the resistance of the second resistor 302 and the third resistor 303 is denoted by R2, a value of the differential value Vout may be represented by the following formula (1).

Vout={(R1−R2)/(R1+R2)}×VDD (1)

Because changes in the resistances R1 and R2 with respect to the temperature are different, the temperature can be obtained based on the differential output Vout. According to the formula (1), the differential output Vout depends on the power supply potential VDD, and thus, the temperature is preferably obtained based on a value Vout/VDD that is obtained by dividing the differential output Vout by the power supply potential VDD.

According to the embodiment, the ESD protection circuit 60 is formed by the NMOS transistor, however, the ESD protection circuit 60 may be formed by the PMOS transistor. In addition, the gate electrode of the NMOS transistor forming the ESD protection circuit 60 may be formed by a process that is common to the process of forming the interconnect layers of the humidity sensing part 21 and the temperature sensing part 22. In this case, it is possible to simplify the manufacturing process of the sensor chip 20. Further, the ESD protection circuit 60 may be formed by the pn junction within the semiconductor substrate. In this case, there is no need to form the gate electrode, and it is possible to further simplify the manufacturing process of the sensor chip 20.

According to the embodiment, the heater controller 33 is provided inside the ASIC chip 30, however, the heater controller 33 may be provided externally to the ASIC chip 30. In other words, the heater control may be performed by an external device (for example, a microcomputer) provided externally to the ASIC chip 30, and the driving voltage to the heater terminal of the sensor chip 20 may be supplied from a power supply different from the ASIC chip 30.

According to the embodiment, the failure judging unit 34 is provided inside the ASIC chip 30, however, the failure judging unit 34 may be provided externally to the ASIC chip 30. In this case, the failure may be judged by an external device (for example, a microcomputer) provided externally to the humidity sensor 10.

The embodiment employs a configuration in which the temperature sensing part 22 and the heater part 23 are provided on the semiconductor substrate. However, the humidity sensor 10 is not limited to such a configuration, and the semiconductor process described above may be used to simultaneously form circuits, such as an amplifier, an Analog-to-Digital Converter (ADC), a Digital-to-Analog Converter (DAC), a regulator, or the like.

The electrostatic capacitance type humidity sensor may have an electrode structure that is the comb-shaped type or the parallel plate type. The comb-shaped type electrode structure includes a pair of opposing comb-shaped electrodes provided on the same plane, and a humidity sensing layer is provided on the comb-shaped electrodes. On the other hand, the parallel plate type electrode structure includes the lower electrode formed on the substrate, and the upper electrode opposing the lower electrode via the humidity sensing layer. The humidity sensing layer is generally made of polyimide.

The separation distance between the electrodes of the electrostatic capacitance type humidity sensor is 0.2 μm to 2 μm, for example, and short, and the electrostatic breakdown may occur due to static electricity because the humidity sensing layer is thin. Since the humidity sensor is manufactured by mounting the sensor chip on the substrate, the electrostatic breakdown may occur in the sensor chip during the manufacturing process, from the time when device structures are formed on a wafer until the time when the chip mounting ends. For this reason, the electrostatic breakdown may occur during the manufacturing process, when the static electricity generated from a manufacturing apparatus or the like is applied to the sensor chip, to deteriorate the yield during the manufacturing process. Hence, it is desirable to improve the resistance to the electrostatic breakdown during the manufacturing process.

The humidity sensor according to the embodiment includes a first semiconductor chip having a humidity sensing part in which a humidity sensing layer is arranged between a pair of electrodes, and a second semiconductor chip that performs a signal processing based on a value output from the humidity sensing part. In addition, the first semiconductor chip further has an ESD protection circuit coupled to input terminals or output terminals of the humidity sensing part. For this reason, it is possible to improve the resistance to the electrostatic breakdown during the manufacturing process.

More particularly, according to the embodiment, the ESD protection circuit 60 is electrically connected to the pads 24b through 24f that function as the input or output terminals of the sensor chip 20. For this reason, an ESD surge entering the sensor chip 20 via the pads 24a through 24f during the manufacturing process, can be released to the ground. Consequently, it is possible to reduce the electrostatic breakdown of the internal circuits, such as the humidity sensing part 21, the temperature sensing part 22, the heater part 23, or the like. Particularly, it is possible to prevent dielectric breakdown of the humidity sensing layer 86, reforming of the material forming the humidity sensing layer 86, or the like caused by the ESD surge applied to the humidity sensing layer 86 of the humidity sensing part 21.

In the prior art, the electrostatic breakdown of the sensor chip caused by the static electricity applied from the manufacturing apparatus, human operator, or the like, may occur during the manufacturing process, from the time when device structures are formed on the wafer until the time when the chips are cut into the ASIC chips or the like and the chip mounting ends. But the sensor chip 20 according to the embodiment includes the ESD protection circuit 60 from the time when the device structures are formed on the wafer, to provide a high resistance to the electrostatic breakdown, and improve the yield during the manufacturing process.

In addition, at least a part of the ESD protection circuit 60 is manufactured by the same manufacturing process as the temperature sensing part 22 and the heater part 23, and it is possible to prevent the manufacturing cost from greatly increasing due to the provision of the ESD protection circuit 60.

Next, a modification of the ESD protection circuit will be described.

FIG. 19 is a circuit diagram illustrating an example of the configuration of the ESD protection circuit 60a according to the modification. As illustrated in FIG. 19, a diode 62 forming the ESD protection circuit 60a according to this modification is a PMOS transistor. More particularly, the diode 62 is formed by the PMOS transistor having a source, a gate, and a back gate thereof that are short-circuited to form the so-called diode connection. The short-circuited part of the PMOS transistor functions as a cathode of the diode 62, and a drain of the PMOS transistor functions as an anode of the diode 62.

The ESD protection circuit 60a according to this modification is electrically connected between the power supply interconnect, and the pads 24b through 24f that function as the input or output terminals of the sensor chip 20. The power supply potential VDD may be the driving voltage applied to the lower electrode 83. In other words, the ESD protection circuit 60a may be electrically connected between the pad 24b that functions as the lower electrode terminal, and the pads 24c through 24f.

FIG. 20 is a diagram illustrating the layer structure of the PMOS transistor forming the ESD protection circuit 60a. This modification uses an n-type semiconductor substrate 70a. The PMOS transistor illustrated in FIG. 20 includes the n-type semiconductor substrate 70a, 2 p-type diffusion layers 71a and 72a formed at the surface of the n-type semiconductor substrate 70a, a contact layer 73a, and the gate electrode 74. The gate electrode 74 is foisted on the surface of the n-type semiconductor substrate 70a via the gate insulating layer 75. The gate electrode 74 is arranged between the 2 p-type diffusion layers 71a and 72a.

For example, the p-type diffusion layer 71a functions as the source, and the p-type diffusion layer 72a functions as the drain. The contact layer 73a is a low-resistance layer (or n-type diffusion layer) for making electrical connection to the n-type semiconductor substrate 70a, to function as the back gate. The p-type diffusion layer 71a, the gate electrode 74, and the contact layer 73a are connected in common and short-circuited. This short-circuited part functions as the cathode, and the p-type diffusion layer 72a functions as the anode.

The n-type semiconductor substrate 70a is an n-type silicon (Si) substrate, for example. In the case of this modification, the sensor chip 20 is preferably formed using the n-type semiconductor substrate 70a. In this case, the heater part 23 may be formed by a p-type diffusion layer, for example.

In addition, the PMOS transistor forming the ESD protection circuit 60a may be formed within an n-well in the p-type semiconductor substrate.

Furthermore, the transistor forming the ESD protection circuit is not limited to one of the NMOS transistor and the PMOS transistor. In other words, the ESD protection circuit may be formed by a combination of NMOS and PMOS transistors.

The humidity sensor 10 according to the embodiment has the stacked structure in which the sensor chip 20 is stacked on the ASIC chip 30. However, the humidity sensor 10 may have a structure other than the stacked structure.

Hence, the embodiments and modifications described above can provide a humidity sensor which can improve the yield during the manufacturing process. It is also possible to improve the resistance to the electrostatic breakdown during the manufacturing process.

In this specification, a first element described as covering a second element may include covering the second element directly, or via one or more third elements. Similarly, a first element described as being formed (or provided) on a second element may include being famed (or provided) directly on the second element, or via one or more third elements.

Further, the present invention is not limited to these embodiments, but various variations, modifications, and substitutions of a part or all of the embodiments may be made without departing from the scope of the present invention.

What is claimed is:

1. A humidity sensor comprising:
a first semiconductor chip having a first side and a second side opposing each other, the first semiconductor chip including a humidity sensing part, and a plurality of pads arranged along the first side;
a second semiconductor chip, mounted with the first semiconductor chip, and configured to process signals input via a plurality of bonding wires coupled to the plurality of pads; and
an encapsulating member having an opening exposing the humidity sensing part, the opening having a center position closer to the second side than a center position of the first semiconductor chip.

2. The humidity sensor as claimed in claim 1, wherein the center position of the first semiconductor chip is located within the opening.

3. The humidity sensor as claimed in claim 1, wherein the first semiconductor chip has a rectangular shape having the first side and the second side as shorter sides of the rectangular shape.

4. The humidity sensor as claimed in claim 1, wherein
the first semiconductor chip further includes a temperature sensing part, and
the opening exposes the humidity sensing part and the temperature sensing part.

5. The humidity sensor as claimed in claim 4, wherein the temperature sensing part has a band-gap structure including one or a plurality of pn junction diodes.

6. The humidity sensor as claimed in claim 1, wherein the encapsulating member is made of an epoxy resin.

7. The humidity sensor as claimed in claim 1, wherein the first semiconductor chip further includes
a semiconductor substrate,
the humidity sensing part includes a first electrode arranged above the semiconductor substrate via an insulating layer, a humidity sensing layer formed on the first electrode, and a second electrode formed on the humidity sensing layer, and
the humidity sensing layer is arranged between the first electrode and the second electrode.

8. The humidity sensor as claimed in claim 7,
wherein the humidity sensing layer is made of polyimide.

9. The humidity sensor as claimed in claim 7, wherein the first semiconductor chip further includes an electrostatic discharge protection circuit coupled to input terminals or output terminals of the humidity sensing part.

10. The humidity sensor as claimed in claim 9, wherein
the first semiconductor chip further includes a temperature sensing part, and
at least a part of a diffusion layer forming the electrostatic discharge protection circuit has a depth, from a surface of the semiconductor substrate, identical to that of a diffusion layer included in the temperature sensing part.

11. The humidity sensor as claimed in claim 10, wherein the temperature sensing part has a band-gap structure including one or a plurality of bipolar transistors having a base and a collector thereof that are coupled.

12. The humidity sensor as claimed in claim 9, wherein
the semiconductor substrate is a p-type semiconductor substrate, and
the electrostatic discharge protection circuit includes a NMOS transistor.

13. The humidity sensor as claimed in claim 9, wherein the humidity sensing layer is made of polyimide.

14. The humidity sensor as claimed in claim 10, wherein the electrostatic discharge protection circuit is further coupled to input terminals or output terminals of the temperature sensing part.
